(19) United States
(12) Patent Application Publication
(10) Pub. No.: US 2004/0121513 A1
(43) Pub. Date: Jun. 24, 2004

(54) Die bonding apparatus and method of die bonding with the apparatus

(75) Inventors: Katsuhiro Taguchi, Tokyo (JP); Yuichi Tanaka, Tokyo (JP); Toru Kimura, Tokyo (JP); Takanori Okita, Tokyo (JP)

Correspondence Address: LEYDIG VOIT & MAYER, LTD, 700 THIRTEENTH ST. NW, SUITE 300, WASHINGTON, DC, 20005-3960, US

(73) Assignees: Renesas Technology Corp., Tokyo (JP); Mitsubishi Electric Engineering Company Limited, Tokyo (JP)

(21) Appl. No.: 10/453,605

(22) Filed: Jun. 4, 2003

(30) Foreign Application Priority Data
Dec. 18, 2002 (JP) 2002-366628

(51) Int. Cl. H01L 21/44

(52) U.S. Cl. 438/106

(57) ABSTRACT

A die bonding apparatus having a bonding tool which, upon mounting a chip on a substrate, adsorbs and holds the chip, and transports the chip to a die bonding position, and bonds the chip onto a surface of the substrate. The bonding tool includes a bonding head, a motor, a load cell, and a controller. The bonding head adsorbs and holds a chip at its end, and applies bonding load to the chip from above. The motor drives said bonding head to move downward such that said bonding head applies bonding load to the chip. The load cell senses said bonding load applied to the chip. The controller sequentially calculates a command voltage output to said motor taking account of said bonding load fed back from said load cell, and speed-controls said motor load such that the output voltage to said motor gradually decreases in response to increment of said bonding.

### BACKGROUND OF THE INVENTION

1. Field of the Invention

The present invention relates to a die bonding apparatus for mounting a chip, such as IC chip, on a substrate, and a method of die bonding with the apparatus.

2. Description of the Related Art

As has been conventionally known, in manufacturing process of a semiconductor device, an assembling process is performed, in which each of chips formed by dicing a IC wafer is incorporated into a package in order to allow such packaging device to be mounted to an electronic instrument. As one step of the assembling process, a die bonding step is known, in which each of chips formed by dicing a IC wafer is bonded on a die pad provided on a surface of a substrate, such as lead frame, via an adhesive material. Such die bonding process is generally performed using a die bonding apparatus, and in the die bonding apparatus, a bonding tool provided with a bonding head is driven in horizontal and perpendicular directions, and each chip is adsorbed and held, and transported to a bonding position, and then bonded onto a surface of substrate. The bonding head is movable in a perpendicular direction and can adsorb and hold a chip.

By the way, to mount a chip on substrate properly, upon bonding the chip to a surface of substrate, bonding load need to be appropriately applied to the top surface of chip by the bonding head. As an apparatus for applying appropriate bonding load, for example, in Japanese Patent laid-open publication Hei 09-199545, an apparatus having a load cell for sensing a bonding load is disclosed, in which a bonding head is moved downward at a specific speed until a bonding load sensed by the load cell begins to increase, and after the beginning of sensed load increment, is moved downward at a more slow speed (creeper speed) until an objective load is arrived.

However, in the apparatus as described above, upon applying bonding load to chip, even though the bonding head can be moved at two speeds, a bonding head is moved downward at a specific speed after sensed load increment until the objective load is arrived and the bonding head is stopped. Accordingly, it is not sufficient to reduce loading impact to chip, which tends to increase closely to the objective load, and to assure security for chip.

### SUMMARY OF THE INVENTION

The present invention has been devised to solve the above-mentioned technical problems, and its object is to provide a die bonding apparatus and a method with the apparatus, which can reduce loading impact to chip and assure security for chip, while achieving proper mount of chip on substrate.

In an aspect of the present invention, there is provided a die bonding apparatus having a bonding tool which, upon mounting a chip on a substrate, can adsorb and hold the chip, and transport the chip to a die bonding position, and bond the chip onto a surface of the substrate. Said bonding tool includes a bonding head, a motor, a load cell, and a controller. The bonding head adsorbs and holds a chip at its end, and applies bonding load to the chip from above. The motor drives said bonding head to move downward such that said bonding head applies bonding load to the chip. The load cell senses said bonding load applied to the chip. The controller sequentially calculates a command voltage output to said motor taking account of said bonding load fed back from said load cell, and speed-controls said motor such that the output voltage to said motor gradually decreases in response to increment of said bonding load.

With the die bonding apparatus, the bonding load can be grasped by the load cell every moment and the voltage output to the motor is sequentially calculated taking account of the bonding load, and thereby, a loading impact onto chip can be reduced and security for chip can be assured.

The bonding tool may include a spring for supporting the bonding head as it is suspended, and canceling weight of the bonding head, and a linear scale for sensing an extension amount of the spring. In this case, the controller could speed-control the motor such that elastic force caused by the spring does not affect a bonding load at bonding head in response to increment of the extension amount fed back from the linear scale.

Thereby, an accidental error of bonding load caused by increment of elastic force of spring can be compensated and affection from elastic force of spring is eliminated, and therefore, bonding load from the bonding head onto chip can be controlled more accurately.

### BRIEF DESCRIPTION OF THE DRAWINGS

FIG. 1 is a side view that schematically shows a bonding tool incorporated into a die bonding apparatus according to a first embodiment of the present invention.

FIG. 2A is a graph representing a relationship between time and motor output voltage.

FIG. 2B is a graph representing a relationship between time and feedback value.

FIG. 3 is a side view that schematically shows a bonding tool incorporated into a die bonding apparatus according to a second embodiment of the present invention.

FIG. 4 is a graph representing a relationship between extension amount of a spring and feedback value of bonding load.

### DETAILED DESCRIPTION OF THE PREFERRED EMBODIMENTS

With reference to the accompanying drawings, various embodiments of the present invention will now be described.

First Embodiment

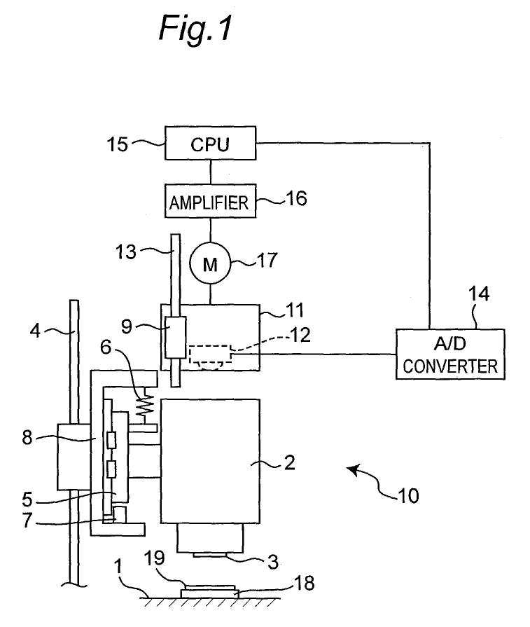

FIG. 1 is a side view that schematically shows a bonding tool incorporated into a die bonding apparatus according to a first embodiment of the present invention. This bonding tool 10 can adsorb and hold a chip 3 and transport the chip to a bonding position, and then bond the chip 3 on a surface of a substrate 18 via an adhesive material 19, such as adhesive film, and has a bonding head 2 which adsorbs and hold a semiconductor chip 3 as an object for bonding at its end and biases the semiconductor chip 3 against the substrate 18 on a stage 1, a depressing member 11 which depresses said bonding head 2 from above in order to allow said bonding head 2 to bias the semiconductor chip 3 against the substrate 18, and a motor 17 which can drive said depressing member 11 to move in a perpendicular direction.

Said bonding head 2 is held by a guide 5 extending at lateral side of head 2 and along a longitudinal direction of head 2. The guide 5 is attached to a support member 8 which is movable in a perpendicular direction along a first pole screw 4, and is allowed to displace within a predetermined range in a perpendicular direction. Further, the guide 5 is connected with support member 8 via a spring 6. This spring 6 can support guide 5 and bonding head 2 as they are suspended, and cancel their weights.

Furthermore, a lock pin 7 is attached to the support member 8, which can regulate displacement of guide 5, that is, displacement of bonding head 2, by engaging with guide 5 to stop it. By releasing this lock pin 7, guide 5 and bonding head 2 supported by guide 3 are allowed to displace within a predetermined range in a perpendicular direction, and in this situation, guide 5 and bonding head 2 are held by spring 6 in same positions as those before releasing the lock pin 7.

The depressing member 11 has a load cell 12 at its under surface. The load cell 12 is depressed to a top surface of bonding head 2 and can sense bonding load applied to semiconductor chip 3. Further, the depressing member 11 is attached to a second pole screw 13 via support member 9 provided on lateral side of depressing member 11, and is allowed to move in a perpendicular direction with a driving force by motor 17.

The bonding tool 10 further has Analog-Digital converter (A/D converter) 14 which converts an analog signal sensed by load cell 12 to a digital signal, a CPU 15 which control driving of motor 17, and an amplifier 16 which amplifies an output signal from CPU 15 and outputs to motor 17. Upon application of bonding load from bonding head onto chip 3, bonding load sensed by load cell 12 is fed back to CPU 15 and CPU 15 sequentially calculates a command voltage output to motor 17, and speed-controls motor 17 so as to acquire a specific bonding load in response to increment of bonding load.

Speed-controlling motor 17 by CPU 15 will be described below. Prior to bonding operation of chip 3 onto substrate 18, bonding head 2 is transported to a bonding position on stage 1 while adsorbing and holding chip 3 at its end. In this embodiment, depressing member 11 which depresses bonding head 2 is not formed integrally with bonding head 2, and thus it is possible to accomplish weight saving for bonding head 2 and bonding head 2 is allowed to transport to bonding position in high-speed. After transporting to bonding position, lock pin 7 is released and bonding head 2 is allowed to displace in a perpendicular direction via spring 6. Then, CPU 15 controls various components incorporated into bonding tool 10 so as to feed a voltage to motor 17 via amplifier 16, and accordingly, depressing member 11 is driven downward and bonding load is applied onto bonding head 2.

Upon driving downward of depressing member 11, if load cell 12 is depressed to a top surface of bonding head 2, bonding load is sensed by load cell 12, and this analog signal representing a bonding load is converted to digital signal through A/D converter 14 and then, is fed back to CPU 15. CPU 15 sequentially calculates a command voltage output to motor 17 taking account of bonding load (feed back value) from load cell 12, and speed-controls motor 17 so as to acquire a specific bonding load. In this case, the command voltage is calculated taking account of feed back value from load cell 12 provided in every cycle of CPU 15 and using the following formula (1).

V_{OUTPUT}={(L_{OBJECTIVE}−X_{FEED BACK})/L_{OBJECTIVE}}×V_{RATING} (1)

wherein V_{OUTPUT} is output voltage;

L_{OBJECTIVE} is objective voltage;

X_{FEED BACK} is feed back value;

V_{RATING} is motor rating voltage.

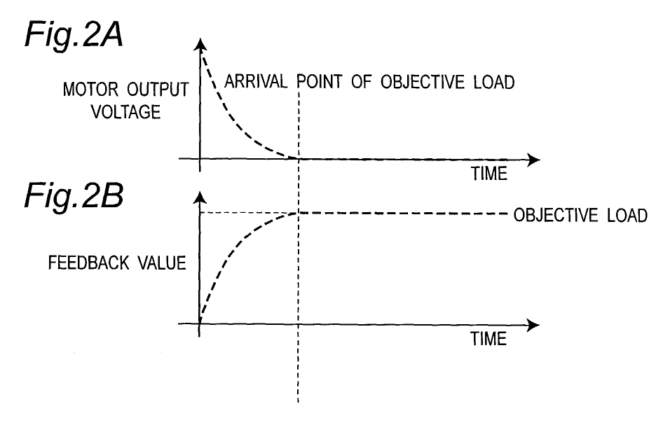

In association with feature of bonding tool 10 as described above, a graph representing relationship between time and voltage output to motor (motor output voltage) is shown in FIG. 2A, and a graph representing relationship between time and feed back value is shown in FIG. 2B. Apparently from the graphs, a feed back value is successively reflected to a voltage output to motor 17, and as a feed back value increases closely to objective load, a voltage output to motor 17 decreases gradually. Namely, the bonding load is closer to objective load the motor-speed becomes lower. Accordingly, a loading impact onto chip 3, which tends to become significant close to the objective load, can be sufficiently reduced.

As described above, with a die bonding apparatus according to first embodiment of the present invention, motor output voltage can be controlled until immediately before the bonding load arrives at the objective load. Therefore, loading impact onto chip 3 can be reduced and security for chip 3 can be assured while achieving proper mount of chip 3 on substrate.

It is noted that chip 3 and substrate 18 may be in noncontact with each other when voltage is applied to motor 17 upon beginning of die bonding in the die bonding apparatus as described above. Thus, bonding operation can be executed without monitoring contact between chip 2 and substrate 18.

Another embodiment will be described below. In the following description, the same elements or components as those in the first embodiment are defined by the same reference numerals, and their description will be omitted.

Second Embodiment

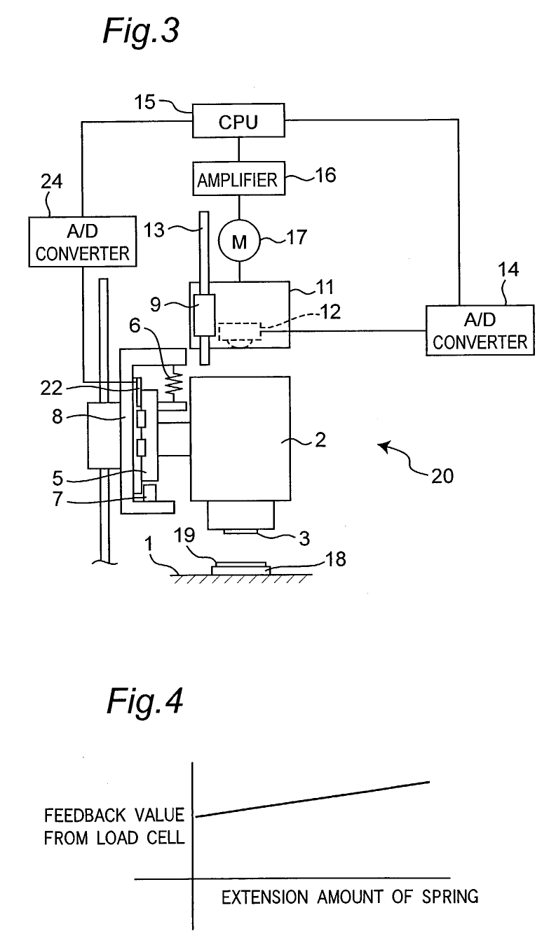

FIG. 3 is a side view that schematically shows a bonding tool incorporated into a die bonding apparatus according to a second embodiment of the present invention. This bonding tool 20 has the same elements or components as those in the first embodiment, and additionally, in the second embodiment, has a linear scale 22 and a A/D converter 24 for compensating elastic force caused by the spring. The linear scale 22 is attached to support member 8 and can sense an extension amount of spring 6 suspending guide 5 and bonding head 2. The A/D converter 24 converts an analog signal representing a position sensed by linear scale 22 to a digital signal, and outputs the digital signal to CPU 15.

In the state of releasing lock pin 7, as described above, guide 5 and bonding head 2 are allowed to displace within a predetermined range in a perpendicular direction, and held by spring 6 in same positions as their positions before releasing the lock pin 7. After beginning of bonding, while bonding head 2 is driven downward, CPU 15 receives the feed back value from load cell 12 and the extension amount of spring 6 from linear scale 22. In CPU 15, the extension amount of spring 6 is added to the voltage output to motor 17. Therefore, affection from the elastic force caused by spring 6 can be avoided.

In more concrete, a relationship between the extension amount of spring 6 sensed by linear scale 22 and the feed back value of bonding load sensed by load cell 12 is stored in a memory incorporated into the die bonding apparatus as a compensation data, and the extension amount of spring 6 is retrieved in every cycle of CPU 15, and added to voltage output to motor 17.

Thus, in CPU 15, voltage output to motor 17 is calculated in response to increment of extension amount of spring 6, that is, increment of elastic force of spring 6, which is fed back from linear scale 22, such that the elastic force of spring 6 does not affect bonding load from bonding head 2 onto chip 3. Thereby, an accidental error of bonding load caused by increment of elastic force of spring 6 can be compensated and affection from elastic force of spring 6 is eliminated, and therefore, bonding load onto chip 3 can be controlled more accurately. As a result, loading impact to chip 3 can be reduced and security for chip 3 can be assured while achieving proper mount of chip 3 on substrate 18.

It is noted that the above linear scale 22 is applicable to not only sensing extension amount of spring 6, but detecting contact state between chip 3 and substrate 18. In this case, sinkage of chip 3 can be monitored during bonding load application started from beginning of contact between chip 3 and substrate 18, and checking the quality of product can be executed based on the sinkage of chip 3.

It is to be understood that the present invention is not limited to the illustrated embodiments, but various modifications and design changes can be made without departing from the spirit and scope of the present invention.

What is claimed is:

1. A die bonding apparatus having a bonding tool which, upon mounting a chip on a substrate, can adsorb and hold the chip, and transport the chip to a die bonding position, and bond the chip onto a surface of the substrate,
said bonding tool comprising:
a bonding head which adsorbs and holds a chip at its end, and applies bonding load to the chip from above;
a motor which drives said bonding head to move downward such that said bonding head applies bonding load to the chip;
a load cell which senses said bonding load applied to the chip; and
a controller sequentially calculates a command voltage output to said motor taking account of said bonding load fed back from said load cell, and speed-controls said motor such that the output voltage to said motor gradually decreases in response to increment of said bonding load.

2. The die bonding apparatus as defined in claim 1, wherein the bonding tool further comprises:
a spring for supporting the bonding head as it is suspended and canceling weight of the bonding head; and
a linear scale for sensing an extension amount of the spring,
wherein the controller speed-controls the motor such that elastic force caused by the spring does not affect a bonding load at bonding head in response to increment of the extension amount fed back from the linear scale.

3. A method of die bonding for mounting a chip on a substrate by transporting the chip to a die bonding position while adsorbing and holding the chip, and bonding the chip onto a surface of the substrate, the method comprising steps of:
sensing the bonding load from a bonding head onto the chip, said bonding head adsorbing and holding the chip at its end and applying bonding load to the chip from above;
sequentially calculating a command voltage output to a motor taking account of said bonding load fed back from said load cell, said motor driving said bonding head to move downward such that the bonding head applies bonding load to the chip; and
speed-controlling said motor such that the output voltage to the motor gradually decreases in response to increment of said bonding load.
